(19) United States
(12) Patent Application Publication
(10) Pub. No.: US 2021/0288619 A1
(43) Pub. Date: Sep. 16, 2021

(54) POWER SUPPLY CIRCUIT AND AMPLIFICATION CIRCUIT

(71) Applicant: SUMITOMO ELECTRIC INDUSTRIES, LTD., Osaka (JP)

(72) Inventor: Mikoto NAKAMURA, Osaka (JP)

(73) Assignee: SUMITOMO ELECTRIC INDUSTRIES, LTD., Osaka (JP)

(21) Appl. No.: 17/258,717

(22) PCT Filed: Jun. 21, 2019
(86) PCT No.: PCT/JP2019/024757

§ 371 Date: Jan. 7, 2021

(30) Foreign Application Priority Data
Jul. 9, 2018 (JP) 2018-130032

(51) Int. Cl. H03F 3/21; H03F 1/02

(52) U.S. Cl. CPC H03F 3/211; H03F 1/0288

(57) ABSTRACT

This power supply circuit is configured to supply power to an amplifier and includes: a power supply line extending by branching from a signal line through which a signal inputted to the amplifier is transferred or a signal outputted from the amplifier is transferred; and a capacitive element having one end connected to a distal end of the power supply line, and another end grounded, the capacitive element leading the signal to a ground, wherein a base end of the power supply line is a branch portion at which the power supply line branches from the signal line, and a line length of the power supply line extending from the branch portion to the distal end is shorter than λ/4, where λ, is a wavelength of the signal.

### TECHNICAL FIELD

The present disclosure relates to a power supply circuit and an amplification circuit.

This application claims priority on Japanese Patent Application No. 2018-130032 filed on Jul. 9, 2018, the entire content of which is incorporated herein by reference.

### BACKGROUND ART

An amplification circuit used in a wireless communication device of a mobile communication system or the like is provided with an amplifier for amplifying a high-frequency signal such as an RF signal. In general, a power supply circuit for supplying power is connected to the drain terminal side of the amplifier (see, for example, Patent Literature 1).

### CITATION LIST

### Patent Literature

PATENT LITERATURE 1: Japanese Laid-Open Patent Publication No. 2015-88881

### SUMMARY OF INVENTION

A power supply circuit according to an embodiment is a power supply circuit configured to supply power to an amplifier, the power supply circuit including: a power supply line extending by branching from a signal line through which a signal inputted to the amplifier is transferred or a signal outputted from the amplifier is transferred; and a capacitive element having one end connected to a distal end of the power supply line, and another end grounded, the capacitive element leading the signal to a ground, wherein a base end of the power supply line is a branch portion at which the power supply line branches from the signal line, and a line length of the power supply line extending from the branch portion to the distal end is shorter than λ/4, where λ, is a wavelength of the signal.

An amplification circuit according to another embodiment includes: an amplifier; a signal line through which a signal inputted to the amplifier is transferred or a signal outputted from the amplifier is transferred; and the power supply circuit described above.

### BRIEF DESCRIPTION OF DRAWINGS

FIG. 1 is a block diagram showing the configuration of a Doherty amplification circuit according to an embodiment.

FIG. 2 is a plan view of the Doherty amplification circuit.

FIG. 3A is a circuit diagram showing an example of the configuration of a first power supply circuit and a carrier-side output matching circuit.

FIG. 3B shows a matching circuit in a case where the line length of a power supply line in FIG. 3A is set to λ/4.

FIG. 4A is a Smith chart showing the load impedance with respect to change in the frequency of a signal in an amplification circuit of an example product.

FIG. 4B is a Smith chart showing the load impedance with respect to change in the frequency of a signal in an amplification circuit of a comparative example product.

FIG. 5 is a circuit diagram showing an example of the configuration of a first power supply circuit and a carrier-side output matching circuit in a modification.

FIG. 6 is a circuit diagram showing the configuration of a harmonic processing circuit provided on the gate terminal side.

FIG. 7 is a circuit diagram showing an example of a conventional power supply circuit.

### DESCRIPTION OF EMBODIMENTS

### Problems to be Solved by the Present Disclosure

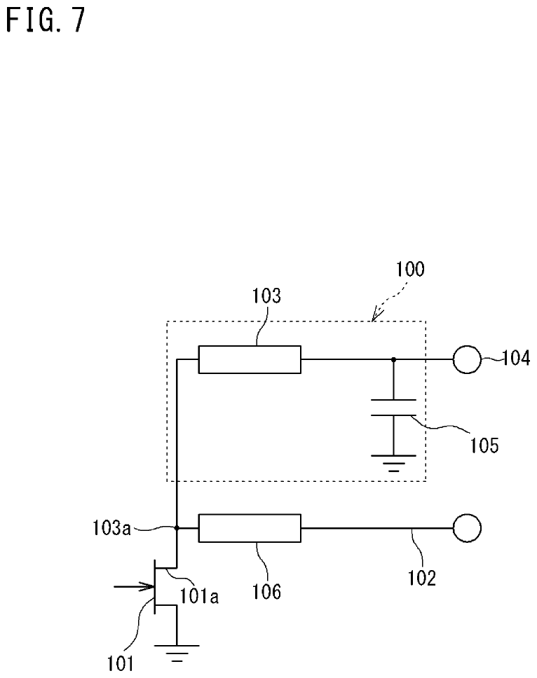

FIG. 7 is a circuit diagram showing an example of a power supply circuit.

In FIG. 7, a power supply circuit 100 includes a power supply line 103 extending by branching from an output line 102 connected to a drain terminal 101a of an amplifier 101, a power source terminal 104 for connecting a DC power source (not shown) to the power supply line 103, and a capacitive element 105 connected between the power supply line 103 and the power source terminal 104.

The capacitance of the capacitive element 105 is set so as to cause short-circuit with respect to a high-frequency signal outputted from the amplifier 101, so that the high-frequency signal is led to the ground, thus inhibiting the high-frequency signal from sneaking into the power source.

The line length of the power supply line 103 is set to λ/4 (λ, is the wavelength of the high-frequency signal outputted from the amplifier 101). That is, the line length from a branch point 103a at which the power supply line 103 is connected to the output line 102, to the power source terminal 104 is λ/4.

Thus, the power supply line 103 and the capacitive element 105 form a short-circuited stub of λ/4 with respect to a high-frequency signal, so that high-frequency signal transfer characteristics are not influenced.

In general, the output line 102 is provided with a matching circuit 106 for making matching of the output impedance of the amplifier 101.

In the matching circuit 106, an inductance element may need to be connected in parallel, for making matching of the output impedance of the amplifier 101.

At this time, in order to prevent a current from the DC power source from flowing to the ground through the inductance element, a capacitive element having such a capacitance as to cause short-circuit with respect to a high-frequency signal needs to be connected between the power supply circuit 100 and the inductance element.

As described above, in a case of including the inductance element in the matching circuit 106, the number of components of the matching circuit 106 increases, and this can hamper size reduction of the matching circuit 106.

Hampering size reduction of the matching circuit 106 leads to hampering of size reduction of the entire amplification circuit, and thus is undesirable.

The present disclosure has been made in view of the above circumstances, and an object of the present disclosure is to provide technology that enables size reduction of a matching circuit connected to an amplifier.

### Effects of the Present Disclosure

According to the present disclosure, size reduction of a matching circuit connected to an amplifier can be achieved.

First, the contents of embodiments are listed and described.

### Outlines of Embodiments

(1) A power supply circuit according to an embodiment is a power supply circuit configured to supply power to an amplifier, the power supply circuit including: a power supply line extending by branching from a signal line through which a signal inputted to the amplifier is transferred or a signal outputted from the amplifier is transferred; and a capacitive element having one end connected to a distal end of the power supply line, and another end grounded, the capacitive element leading the signal to a ground, wherein a base end of the power supply line is a branch portion at which the power supply line branches from the signal line, and a line length of the power supply line extending from the branch portion to the distal end is shorter than λ/4, where λ, is a wavelength of the signal.

In the power supply circuit having the above configuration, since the line length of the power supply line is shorter than λ/4, the power supply line functions as an inductance element connected in parallel to the signal line.

Therefore, even in a case where it is necessary to connect an inductance element in parallel in the matching circuit provided to the signal line and making impedance matching for the amplifier, the inductance element that should be provided to the matching circuit can be substituted by the power supply line.

As a result, the inductance element that should be provided to the matching circuit and a capacitive element needed for connection of the inductance element need not be provided to the matching circuit, so that size reduction of the matching circuit can be achieved.

(2) In the above power supply circuit, preferably, the line length of the power supply line is longer than λ/16 and shorter than λ/8.

Thus, the inductance of the power supply line can be set to an appropriate inductance in impedance matching for the amplifier.

(3) In the above power supply circuit, preferably, the amplifier is stored in one package, together with another amplifier.

In this case, the signal line connected to the amplifier and a signal line for another amplifier are arranged side by side, so that the space around the signal lines are limited. However, even in this case, since size reduction of the matching circuit provided to the signal line can be achieved, the matching circuit can be appropriately arranged in spite of the limited space around the signal lines.

(4) The above power supply circuit may further include a harmonic processing circuit connected between the distal end of the power supply line and a power source supplying power to the power supply line, the harmonic processing circuit being configured to process a harmonic of the signal. In this case, the power supply circuit can perform harmonic processing for the signal.

(5) An amplification circuit according to another embodiment includes: an amplifier; a signal line through which a signal inputted to the amplifier is transferred or a signal outputted from the amplifier is transferred; and the power supply circuit described in any one of the above (1) to (4).

### Details of Embodiments

Hereinafter, preferred embodiments will be described with reference to the drawings.

At least some parts of the embodiments described below may be combined together as desired.

[Configuration of Amplification Circuit]

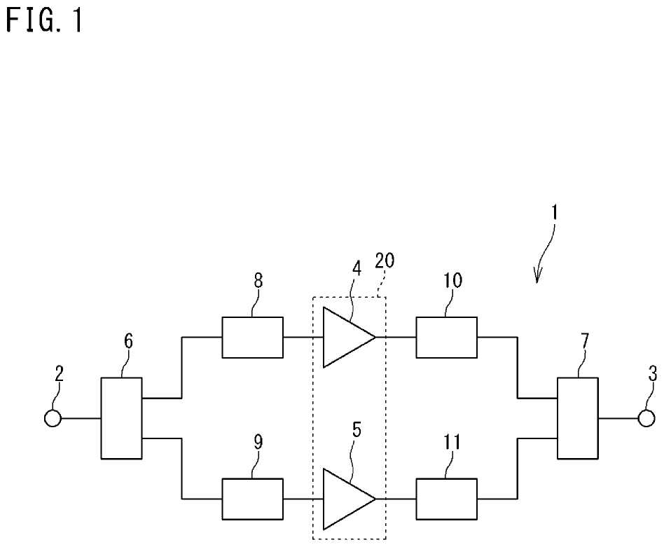

FIG. 1 is a block diagram showing the configuration of a Doherty amplification circuit according to an embodiment.

The Doherty amplification circuit 1 is mounted on a wireless communication device such as a base station device in a mobile communication system, and performs amplification of a transmission signal (RF signal) having a radio frequency.

The Doherty amplification circuit 1 amplifies an RF signal (input signal) given to an input terminal 2, and outputs the amplified signal from an output terminal 3.

As shown in FIG. 1, the Doherty amplification circuit 1 includes a carrier amplifier 4, a peak amplifier 5 provided in parallel to the carrier amplifier 4, a distributor 6, a synthesizer 7 for synthesizing outputs of the carrier amplifier 4 and the peak amplifier 5, a carrier-side input matching circuit 8, a peak-side input matching circuit 9, a carrier-side output matching circuit 10, and a peak-side output matching circuit 11.

The distributor 6 is connected at a stage subsequent to the input terminal 2, and distributes the RF signal given from the input terminal 2, to the carrier amplifier 4 and the peak amplifier 5.

The output of the distributor 6 is given to the carrier amplifier 4 via the carrier-side input matching circuit 8, and also given to the peak amplifier 5 via the peak-side input matching circuit 9.

The carrier-side input matching circuit 8 makes impedance matching with respect to a fundamental wave between the distributor 6 side and the carrier amplifier 4 side. The peak-side input matching circuit 9 makes impedance matching with respect to a fundamental wave between the distributor 6 side and the peak amplifier 5 side.

The carrier amplifier 4 is an amplifier for constantly amplifying the given input signal. The peak amplifier 5 is an amplifier for amplifying an input signal when power of the input signal is equal to or greater than a predetermined value. The carrier amplifier 4 and the peak amplifier 5 are high electron mobility transistors (HEMT) using gallium nitride (GaN), for example.

The carrier amplifier 4 and the peak amplifier 5 are implemented on one integrated circuit, and stored in one package 20.

The output of the carrier amplifier 4 is given to the synthesizer 7 via the carrier-side output matching circuit 10.

The output of the peak amplifier 5 is given to the synthesizer 7 via the peak-side output matching circuit 11.

The carrier-side output matching circuit 10 makes impedance matching with respect to a fundamental wave between the carrier amplifier 4 side and the synthesizer 7 side. The peak-side output matching circuit 11 makes impedance matching with respect to a fundamental wave between the peak amplifier 5 side and the synthesizer 7 side.

The synthesizer 7 synthesizes the output of the carrier amplifier 4 and the output of the peak amplifier 5. The synthesizer 7 gives the synthesized output as an output signal to the output terminal 3.

The output terminal 3 outputs the output signal given from the synthesizer 7.

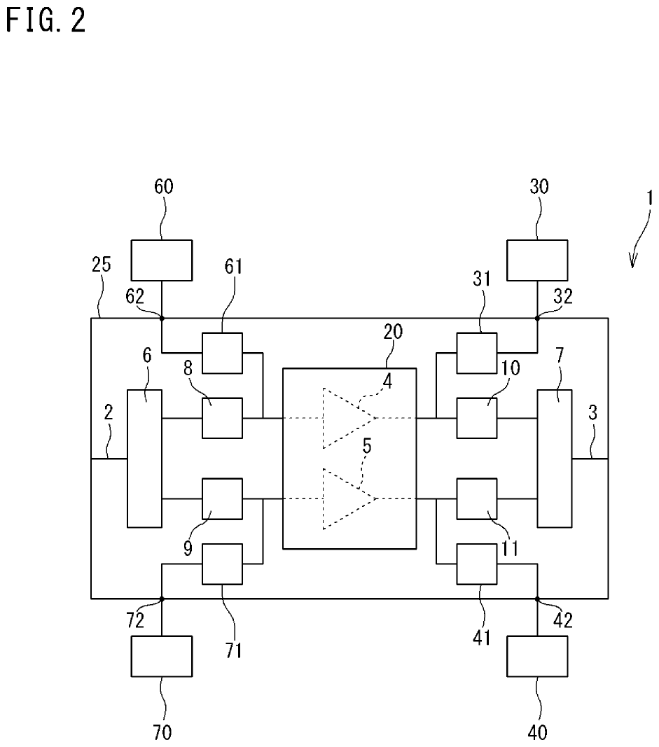

FIG. 2 is a plan view of the Doherty amplification circuit 1.

As shown in FIG. 2, the package 20 in which the amplifiers 4, 5 are stored, the input and output terminals 2, 3, the distributor 6, the synthesizer 7, and the matching circuits 8, 9, 10, 11 are implemented on a circuit board 25.

A first drain power source 30, a second drain power source 40, a first gate power source 60, and a second gate power source 70 which are provided outside the circuit board 25 are connected to the Doherty amplification circuit 1.

The first drain power source 30 is a DC power source for supplying power to the drain terminal of the carrier amplifier 4, and is connected to the drain terminal of the carrier amplifier 4 via a power source terminal 32 and a first power supply circuit 31 connected to the power source terminal 32.

The second drain power source 40 is a DC power source for supplying power to the drain terminal of the peak amplifier 5, and is connected to the drain terminal of the peak amplifier 5 via a power source terminal 42 and a second power supply circuit 41 connected to the power source terminal 42.

The first gate power source 60 is a DC power source for supplying power to the gate terminal of the carrier amplifier 4, and is connected to the gate terminal of the carrier amplifier 4 via a power source terminal 62 and a third power supply circuit 61 connected to the power source terminal 62.

The second gate power source 70 is a DC power source for supplying power to the gate terminal of the peak amplifier 5, and is connected to the gate terminal of the peak amplifier 5 via a power source terminal 72 and a fourth power supply circuit 71 connected to the power source terminal 72.

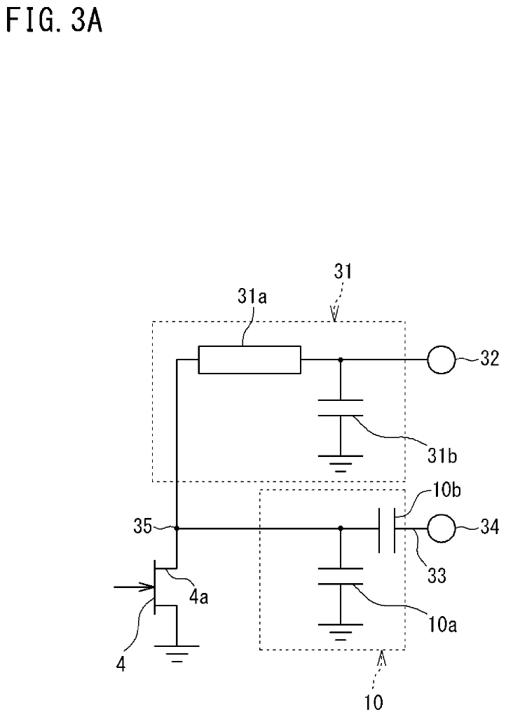

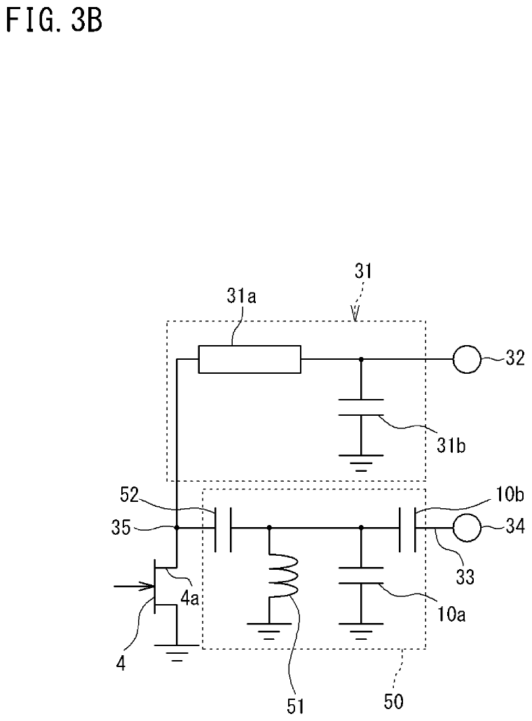

FIG. 3A is a circuit diagram showing an example of the configuration of the first power supply circuit 31 and the carrier-side output matching circuit 10. It is noted that the second power supply circuit 41 has the same configuration as the first power supply circuit 31. Therefore, only the first power supply circuit 31 will be described here.

As shown in FIG. 3A, an output line 33 is connected to a drain terminal 4a of the carrier amplifier 4. The output line 33 connects the drain terminal 4a and a terminal 34 leading to the synthesizer 7. Thus, the output of the carrier amplifier 4 is given to the synthesizer 7.

The first power supply circuit 31 branches from the output line 33 and is connected to the power source terminal 32 leading to the power source terminal 32, thus forming a circuit for supplying power from the first drain power source 30 to the drain terminal 4a side.

The first power supply circuit 31 includes a power supply line 31a extending by branching from the output line 33, and a first capacitive element 31b.

The power supply line 31a is a microstrip line formed between the power source terminal 32 and a branch portion 35 at which the power supply line 31a branches from the output line 33. That is, a base end of the power supply line 31a is the branch portion 35. In addition, a distal end of the power supply line 31a is connected to the power source terminal 32.

The first capacitive element 31b has one end connected between the power source terminal 32 and the power supply line 31a, and another end grounded. That is, the one end of the first capacitive element 31b is connected to the distal end of the power supply line 31a. That is, the power supply line 31a extends from the branch portion 35 as the base end, to the connection portion to which the first capacitive element 31b is connected, as the distal end.

The capacitance of the first capacitive element 31b is set so as to cause short-circuit with respect to an output (RF signal) from the amplifier 4, so that the output from the amplifier 4 is led to the ground. Thus, the first capacitive element 31b inhibits the output from the amplifier 4 from sneaking into the first drain power source 30.

Here, the line length (line length from the branch portion 35 to the connection portion with the first capacitive element 31b) of the power supply line 31a in the present embodiment is set to be shorter than λ/4, where λ, is the wavelength of the RF signal.

Therefore, the power supply line 31a functions as an inductance element connected in parallel to the output line 33.

The branch portion 35 may be provided to the drain terminal 4a. In this case, the drain terminal 4a is the base end of the power supply line 31a.

The carrier-side output matching circuit 10 is provided to the output line 33. The carrier-side output matching circuit 10 includes a capacitive element 10a connected in parallel to the output line 33, and a capacitive element 10b connected in series to the output line 33.

In the present embodiment, since the power supply line 31a functions as an inductance element connected in parallel to the output line 33, impedance matching of the output of the carrier amplifier 4 in this circuit 1 is made by the power supply line 31a and the carrier-side output matching circuit 10.

Therefore, the line length of the power supply line 31a and the capacitances of the capacitive elements 10a, 10b of the carrier-side output matching circuit 10 are set to such values that enable the output of the carrier amplifier 4 to be impedance-matched.

Here, FIG. 3B shows a matching circuit 50 that enables impedance matching as with the first power supply circuit 31 and the carrier-side output matching circuit 10 in FIG. 3A, in a case where the line length of the power supply line 31a in FIG. 3A is set to λ/4.

In FIG. 3B, since the line length of the power supply line 31a is λ/4, the first power supply circuit 31 is open-circuited with respect to the output of the carrier amplifier 4.

Therefore, the matching circuit 50 in FIG. 3B includes, in addition to the capacitive element 10a and the capacitive element 10b, an inductance element 51 for realizing the inductance element function imparted to the power supply line 31a in FIG. 3A.

The inductance element 51 has one end connected to the output line 33 and another end grounded, and is connected in parallel to the output line 33. The inductance element 51 is provided, to the matching circuit 50, as an element needed for matching of the output impedance of the carrier amplifier 4.

Further, the matching circuit 50 includes, at a stage preceding the inductance element 51, a capacitive element 52 connected in series to the output line 33.

The capacitive element 52 has such a capacitance as to cause short-circuit with respect to an RF signal. The capacitive element 52 is connected for preventing a DC current from the first drain power source 30 from flowing to the ground through the inductance element 51. That is, the capacitive element 52 is provided in association with the inductance element 51.

On the other hand, in the first power supply circuit 31 of the present embodiment shown in FIG. 3A, the line length of the power supply line 31a is shorter than λ/4, and therefore the power supply line 31a functions as an inductance element connected in parallel to the output line 33.

Therefore, the inductance element 51 provided to the matching circuit 50 shown in FIG. 3B can be substituted by the power supply line 31a, so that the inductance element 51 and the capacitive element 52 needed in association with the inductance element 51 need not be provided to the carrier-side output matching circuit 10. This enables size reduction of the carrier-side output matching circuit 10.

That is, in the first power supply circuit 31 of the present embodiment, even in a case where it is necessary to connect an inductance element in parallel in the carrier-side output matching circuit 10, the inductance element that should be provided to the carrier-side output matching circuit 10 and a capacitive element needed in association with the inductance element need not be provided to the carrier-side output matching circuit 10, thus enabling size reduction of the carrier-side output matching circuit 10.

While the line length of the power supply line 31a is shorter than λ/4, further, it is more preferable that the line length is longer than λ/16 and shorter than λ/8.

In this case, the inductance of the power supply line 31a can be set to an appropriate inductance for matching of the output impedance of the carrier amplifier 4.

In the present embodiment, since the carrier amplifier 4 and the peak amplifier 5 are stored in one package 20, the carrier-side output matching circuit 10 and the peak-side output matching circuit 11 are arranged side by side (FIG. 2), so that the space around the matching circuits 10, 11 is limited.

However, even in this case, since size reduction of the carrier-side output matching circuit 10 can be achieved in the present embodiment, the matching circuits 10, 11 can be appropriately arranged in spite of the limited space around the matching circuits 10, 11.

Next, a verification test will be described in which the load impedance in the amplification circuit having the power supply circuit of the present embodiment was calculated to verify that the power supply line of the power supply circuit functioned as an inductance element.

An example product and a comparative example product used in the verification test were configured as an amplification circuit including an amplifier for amplifying an RF signal with a frequency of 3.6 GHz and a power supply circuit for supplying power to the amplifier.

The test method was as follows: the load impedances of the example product and the comparative example product were calculated through computer simulation and compared with each other to verify whether or not the power supply line of the power supply circuit of the present embodiment functioned as the inductance element.

The example product had a circuit configuration in which the capacitive element 10a and the capacitive element 10b were removed in the first power supply circuit 31 and the carrier-side output matching circuit 10 shown in FIG. 3A, and the line length of the power supply line 31a was set to a value shorter than λ/4.

The comparative example product had a circuit configuration in which the capacitive element 10a and the capacitive element 10b were removed in the first power supply circuit 31 and the matching circuit 50 shown in FIG. 3B, and the line length of the power supply line 31a was set to λ/4.

Exemplary settings for elements of the example product and the comparative example product are as follows.

The line length of the power supply line 31a in the example product: 3.5 mm (millimeter)

The line length of the power supply line 31a in the comparative example product: 13 mm (millimeter)

The inductance of the inductance element 51 in the comparative example product: 1 nH (nanohenry)

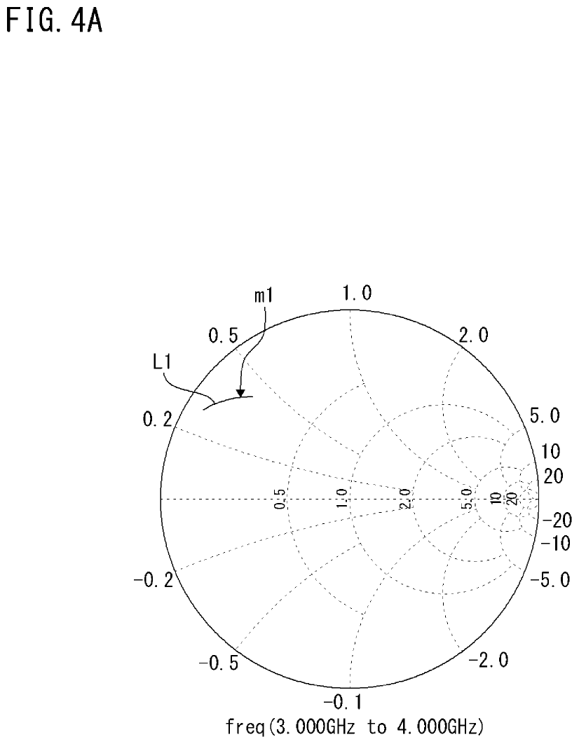

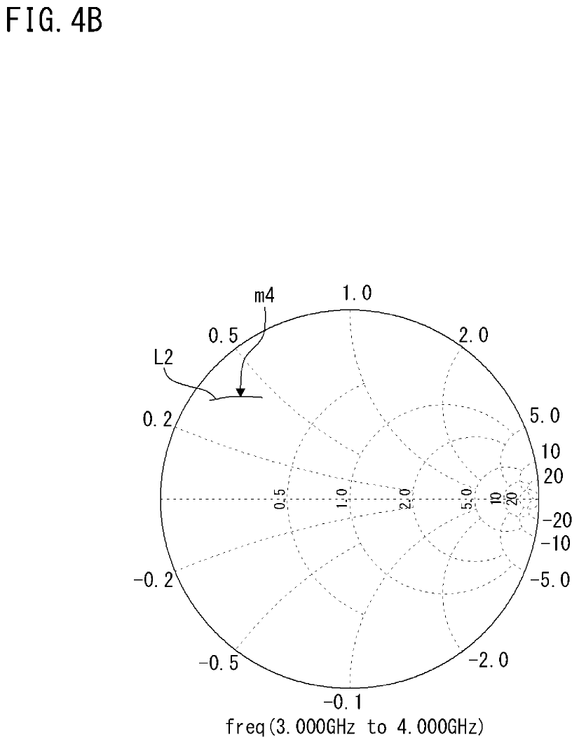

FIG. 4A is a Smith chart showing the load impedance with respect to change in the frequency of a signal in the amplification circuit of the example product, and FIG. 4B is a Smith chart showing the load impedance with respect to change in the frequency of a signal in the amplification circuit of the comparative example product.

In FIG. 4A, a line L1 represents the load impedance while the frequency of the signal is changed from 3.0 GHz to 4.0 GHz, and a marker m1 on the line L1 indicates the load impedance at a frequency of 3.6 GHz.

In FIG. 4B, a line L2 represents the load impedance while the frequency of the signal is changed from 3.0 GHz to 4.0 GHz, and a marker m4 on the line L2 indicates the load impedance at a frequency of 3.6 GHz.

The load impedance at the marker m1 has a magnitude of 0.725 and a phase of 137.351.

The load impedance at the marker m4 has a magnitude of 0.729 and a phase of 137.025.

Thus, the load impedances of the example product and the comparative example product are almost the same, so that it can be confirmed that the power supply line of the power supply circuit in the present embodiment functions as an inductance element.

### OTHERS

The above embodiment is merely illustrative in all aspects and should not be recognized as being restrictive.

For example, in the above embodiment, the case of the Doherty amplification circuit 1 has been described. However, an amplification circuit using a package storing a single amplifier is also applicable.

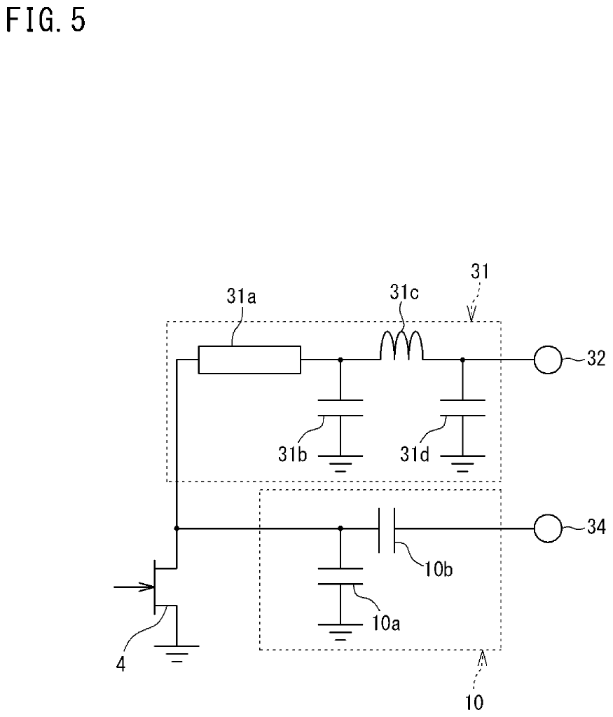

In the first power supply circuit 31 of the above embodiment, a configuration including the power supply line 31a and the first capacitive element 31b has been shown as an example. However, for example, as shown in FIG. 5, a configuration including a harmonic processing circuit for processing harmonics of the output of the carrier amplifier 4 may be employed.

In the first power supply circuit 31 shown in FIG. 5, an inductance element 31c and a second capacitive element 31d forming a harmonic processing circuit are provided between the power source terminal 32 and one end of the first capacitive element 31b connected to the distal end of the power supply line 31a. The inductance element 31c is connected in series between the one end of the first capacitive element 31b and the power source terminal 32. The second capacitive element 31d has one end connected between the power source terminal 32 and the inductance element 31c, and another end grounded.

In this case, the first power supply circuit 31 can perform harmonic processing for the output of the carrier amplifier 4.

The inductance element 31c and the second capacitive element 31d forming the harmonic processing circuit may be configured as a lumped constant circuit or may be configured as a distributed constant circuit.

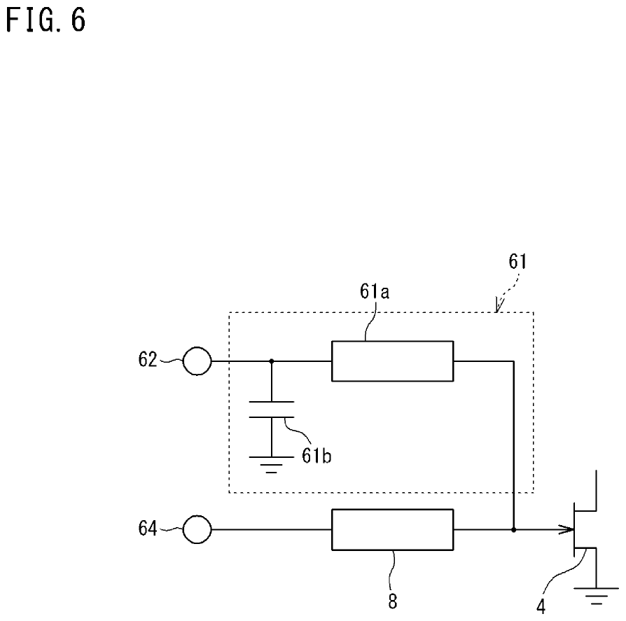

In the above embodiment, the case where the line lengths of the power supply lines in the first power supply circuit 31 connected to the drain terminal of the carrier amplifier 4 and the second power supply circuit 41 connected to the drain terminal of the peak amplifier 5 are set to be shorter than λ/4, has been shown as an example. However, as shown in FIG. 6, the line length of the power supply line 61a provided in the third power supply circuit 61 for supplying a gate voltage from the first gate power source 60 may be set to be shorter than λ/4.

The third power supply circuit 61 includes a power supply line 61a and a capacitive element 61b. The capacitive element 61b has one end connected between the power source terminal 62 and the power supply line 61a, and another end grounded.

Also in this case, the inductance element that should be provided to the carrier-side input matching circuit 8 can be substituted by the power supply line 61a. Therefore, even in a case where it is necessary to provide an inductance element to the carrier-side input matching circuit 8, the inductance element that should be provided and a capacitive element needed in association with the inductance element need not be provided to the carrier-side input matching circuit 8, so that size reduction of the carrier-side input matching circuit 8 can be achieved.

The same applies to the second gate power source 70 side, i.e., the line length of the power supply line provided in the fourth power supply circuit 71 may be set to be shorter than λ/4.

The scope of the present disclosure is defined by the scope of the claims rather than by the description above, and is intended to include meaning equivalent to the scope of the claims and all modifications within the scope.

### REFERENCE SIGNS LIST

1 Doherty amplification circuit
2 input terminal
3 output terminal
4 carrier amplifier
4a drain terminal
5 peak amplifier
6 distributor
7 synthesizer
8 carrier-side input matching circuit
9 peak-side input matching circuit
10 carrier-side output matching circuit
10a capacitive element
10b capacitive element
11 peak-side output matching circuit
20 package
25 circuit board
30 first drain power source
31 first power supply circuit
31a power supply line
31b first capacitive element
31c inductance element
31d second capacitive element
32 power source terminal
33 output line
34 terminal
35 branch portion
40 second drain power source
41 second power supply circuit
42 power source terminal
50 matching circuit
51 inductance element
52 capacitive element
60 first gate power source
61 third power supply circuit
61a power supply line
61b capacitive element
62 power source terminal
70 second gate power source
71 fourth power supply circuit
72 power source terminal
L1 line
L2 line
m1 marker
m4 marker

1. A power supply circuit configured to supply power to an amplifier, the power supply circuit comprising:
a power supply line extending by branching from a signal line through which a signal inputted to the amplifier is transferred or a signal outputted from the amplifier is transferred; and
a capacitive element having one end connected to a distal end of the power supply line, and another end grounded, the capacitive element leading the signal to a ground, wherein
a base end of the power supply line is a branch portion at which the power supply line branches from the signal line, and
a line length of the power supply line extending from the branch portion to the distal end is shorter than λ/4, where λ, is a wavelength of the signal.

2. The power supply circuit according to claim 1, wherein
the line length of the power supply line is longer than λ/16 and shorter than λ/8.

3. The power supply circuit according to claim 1, wherein
the amplifier is stored in one package, together with another amplifier.

4. The power supply circuit according to claim 1, further comprising a harmonic processing circuit connected between the distal end of the power supply line and a power source supplying power to the power supply line, the harmonic processing circuit being configured to process a harmonic of the signal.

5. An amplification circuit comprising:
an amplifier;
a signal line through which a signal inputted to the amplifier is transferred or a signal outputted from the amplifier is transferred; and
the power supply circuit according to claim 1.
